(19) United States
(12) Patent Application Publication
(10) Pub. No.: US 2025/0125157 A1
(43) Pub. Date: Apr. 17, 2025

(54) OPTIMUM MATERIAL STACKS FOR SEMICONDUCTOR CONTACTS

(71) Applicant: Applied Materials, Inc., Santa Clara, CA (US)

(72) Inventors: Michael HAVERTY, Santa Clara, CA (US); Avgerinos V. GELATOS, Scotts Valley, CA (US); Gaurav THAREJA, Santa Clara, CA (US); Lauren Mary BAGBY, Palo Alto, CA (US); Lakmal C. KALUTARAGE, San Jose, CA (US); Jeffrey W. ANTHIS, San Jose, CA (US); Archana KUMAR, Mountain View, CA (US)

(21) Appl. No.: 18/634,659

(22) Filed: Apr. 12, 2024

Related U.S. Application Data
(60) Provisional application No. 63/543,709, filed on Oct. 11, 2023.

(51) Int. Cl. H01L 21/3205; H01L 21/48

(52) U.S. Cl. CPC H01L 21/32053; H01L 21/4814; H01L 2221/1068

(57) ABSTRACT

The methods of the present disclosure enable formation of highly conductive contacts that facilitate in increasing the device speed and lowering the operating voltages of semiconductor devices such as, but not limited to, metal-on-semiconductor (MOS) transistors and the like. In one embodiment, the methods create the optimal contacts, useful in N type or P type MOS devices, by forming metal-insulator-semiconductor (MIS) contact structure or a non-stoichiometric layer contact structure. It is noted that N type or P type contacts require different work function metals to achieve a low Schottky barrier height (SBH).

### CROSS-REFERENCE TO RELATED APPLICATIONS

This application claims priority to U.S. Provisional Application Ser. No. 63/543,709 filed Oct. 11, 2023, which is herein incorporated by reference in its entirety.

### FIELD

Embodiments of the present principles generally relate to semiconductor manufacturing.

### BACKGROUND

The speed of semiconductor devices such as metal-on-semiconductor transistors are dependent on the resistance of the source/drain contacts. The lower the resistance, the faster the speed of the transistor. Traditionally, in order to reduce the contact resistance, titanium silicide-based materials were applied to the source/drain Epi surfaces at the metal contact interface. Transistors have different compositions of materials when the transistor is a type N-type transistor as opposed to a type P-type transistor. The inventors have observed that the titanium silicide-based materials, however, are limited in that the titanium silicide-based materials are not optimal for either type of transistor and cannot be adjusted based on the transistor type. In addition, the inventors have observed that while the high resistance associated with the titanium silicide-based materials were acceptable for large scale devices, the high resistances are detrimental to smaller scale devices.

Accordingly, the inventors have provided methods for producing an enhanced interface between source/drain contact surfaces and metal contacts, yielding improved resistance, leading to superior performance, lower operating voltages, and faster speeds.

### SUMMARY

Methods and apparatus for forming low resistance interfaces between contact surfaces and metal contacts are provided herein.

Embodiments of the present disclosure provide a method of forming an electrical contact. The method includes depositing an insulating layer that comprises a first material on a contact surface, wherein the first material has a first formation energy, and depositing a conductive layer that comprises a second material over a surface of the insulating layer, wherein the second material has a second formation energy, and the second formation energy is less than the first formation energy.

Embodiments of the present disclosure provide a method of forming an electrical contact. The method includes depositing a non-stoichiometric layer that comprises a first material on a contact surface, wherein the contact surface comprises silicon (Si), and the first material comprises oxygen and the first material is non-stoichiometrically deficient in oxygen.

Embodiments of the present disclosure provide a semiconductor structure. The semiconductor structure includes an insulating layer that comprises a first material on a contact surface, wherein the first material has a first formation energy, and a conductive layer that comprises a second material over a surface of the insulating layer, wherein the second material has a second formation energy, and the second formation energy is less than the first formation energy.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming a metal-insulator-semiconductor (MIS) contact in accordance with some embodiments of the present principles.

FIGS. 2A, 2B, and 2C depict cross-sectional views of a semiconductor structure including source/drain Epi surfaces formed on a substrate during different portions of the method illustrated in FIG. 1, according to some embodiments of the present disclosure provided herein.

FIG. 3 is a method of forming a conductive electrical contact in accordance with some embodiments of the present principles.

FIGS. 4A and 4B depict cross-sectional views of a semiconductor structure including source/drain Epi surfaces formed on a substrate during different portions of the method illustrated in FIG. 3, according to some embodiments of the present disclosure provided herein.

FIG. 5 depicts a top-down view of an integrated tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods of the present disclosure enable formation of highly conductive contacts that facilitate in increasing the device speed and lowering the operating voltages of semiconductor devices such as, but not limited to, metal-on-semiconductor (MOS) transistors and the like. The methods create the optimal contacts, useful in N type or P type MOS devices, by forming metal-insulator-semiconductor (MIS) contact structure. N type or P type contacts require different work function metals to achieve a low Schottky barrier height (SBH). A single metal silicide with fixed work function cannot achieve low SBH for both N type and P type contacts. A tunable work function metal silicide as found in the present methods can adjust the work functions to target the lowest contact resistance for N type and P type separately.

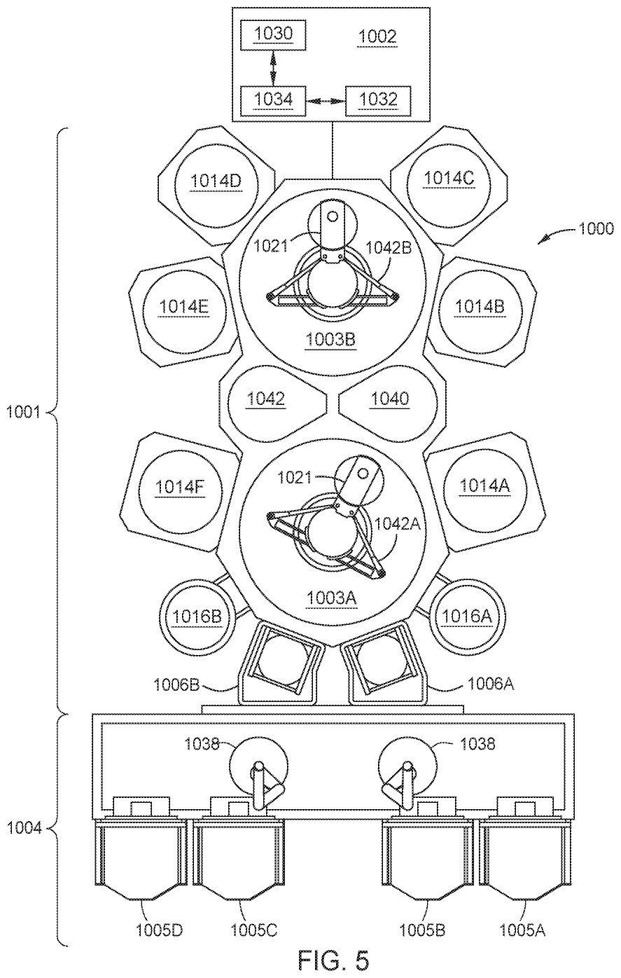

In some embodiments, a MIS contact structure is preferably formed on an N type contact of a CMOS device. In general, the MIS contact structure will include the formation of insulating layer that is more stable than the conductive layer formed on top of insulating layer, which is disposed on the semiconductor containing contact surface. When used in N-type contact structures it is desirable for the work-function (WF) of the conductive layer to be as low as possible to reduce the Schottky barrier height. In some embodiments, the insulating layers may include, but are not limited to, materials within Group 3 and the lanthanide series of chemical elements. In one example, the insulating layers include at least one oxide or nitride of one of the elements within the lanthanide series of chemical elements. In one example of an MIS contact structure, the insulating layer(s) include at least one of HfO₂, La₂O₃, Y₂O₃, Ta₂O₅, SiO₂, Eu₂O₃, SC₂O₃, Gd₂O₃, and ZrO₂, and the conductive layer includes a metal selected from the group of Eu, Mg, V, Mn, Al, Bi, Zn, In, W, and As. In one specific example, the insulating layers includes Y₂O₃ and the conductive layer includes Al, which are formed over semiconductor contact that can include Si, Ge, P, and As, combinations thereof, or other useful contact material. The insulating layers can have a thickness of about 1 to 2 nanometers (nm) that is deposited by a chemical vapor deposition (CVD) or atomic layer deposition (ALD) process. The processes disclosed herein can be performed within a single cluster tool as shown in FIG. 5 by use of a physical vapor deposition (PVD), CVD and/or ALD deposition process.

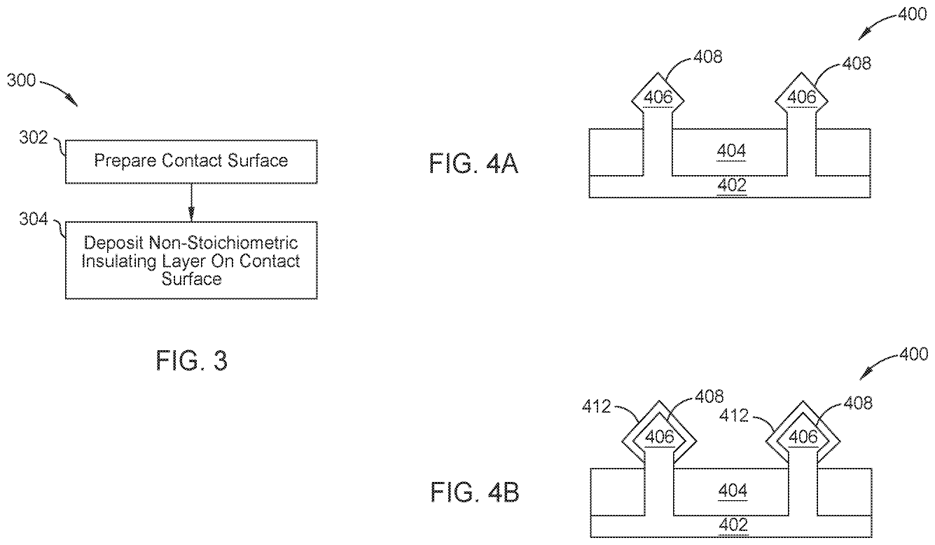

Traditional approaches rely on a single work function silicide for both N type and P type contacts or by depositing a different metal on either N type or P type Epi surfaces to achieve different silicides for N type and P type contacts. In one embodiment of the present disclosure, as discussed in relation to FIGS. 3 and 4, a single non-stoichiometric metal oxide (e.g., sub-oxide or sub-nitride) be used to lower the resistance of a contact, such as the N type or P type contacts, by changing the oxygen content (e.g., reduced amount oxygen or nitrogen) in the metal oxide to achieve different work function. In some embodiments, the single non-stoichiometric metal oxide includes a layer that has a reduced non-stoichiometric amount of oxygen or nitrogen that allows the layer to be conductive and have a low work-function for use in N-type contact structures and a high work-function in P-type contact structures.

In brief, a pre-clean process is used to remove any oxide from silicon, silicon phosphide (SiP), or silicon germanium (SiGe) source/drain Epi surfaces, which is followed by depositing an insulating layer on the surface of the contacts by use of a first precursor, and then a conductive layer (e.g., metal) by use of a second precursor is formed thereon inside the contact trenches. An optional capping layer (e.g., TiN layer) may be formed over the conductive layer and/or an anneal process may be performed.

For the sake of brevity, contact surfaces described herein may include surfaces of epitaxially grown structures or “Epi surfaces” or further abbreviated as “Epi” or simply “contact surfaces” described herein may include surfaces of source/drain Epi structures of MOS transistors and/or other semiconductor structures and the like. However, the methods of the present disclosure may be used to reduce interface resistance between the contact surfaces and MIS contact structure.

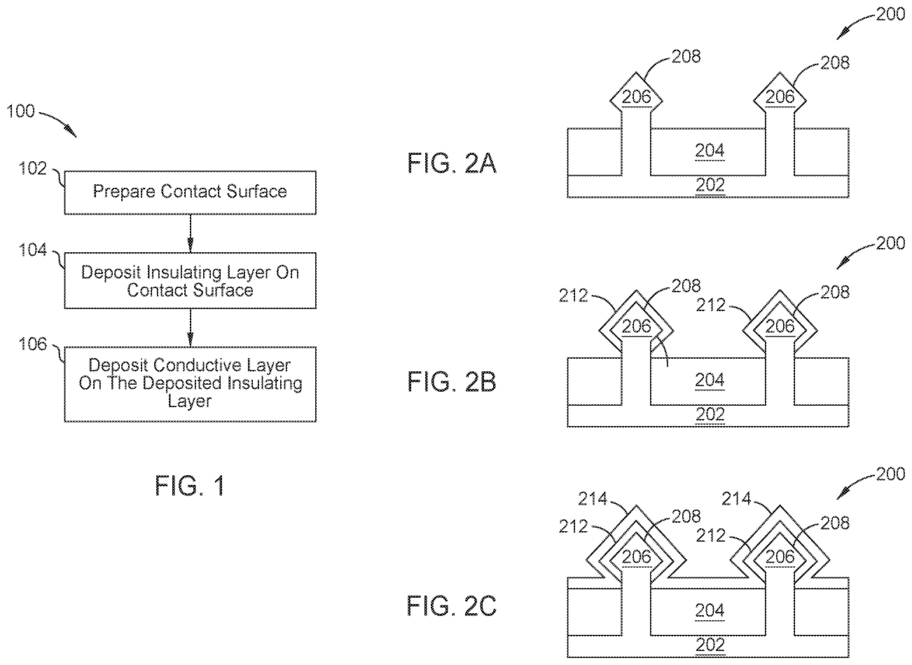

FIG. 1 is a method 100 of reducing interface resistance of an Epi surface on a substrate in accordance with some embodiments. FIGS. 2A, 2B, and 2C are referenced during the discussion of the method 100 for illustrative purposes. As shown in FIG. 2A, an MIS contact structure 200 includes an epitaxially grown source/drain (S/D) layer 202 (e.g., phosphorous (P) doped Si) of approximately 30 nm to approximately 40 nm in thickness, a silicon cap layer 204 of approximately 1 nm to approximately 10 nm in thickness, and Epi contact structures 206 (e.g., silicon germanium (SiGe)).

In block 102 of the method 100, a surface 208 of the Epi contact structure 206 (referred to simply as “contact surface”) is pre-cleaned to remove any contamination and/or oxides formed on the contact surface 208. In one example, the pre-clean process may include etching the contact surface 208 by a plasma assisted etch process using H₂/Ar gas performed in a process chamber, such as one available from Applied Materials of Santa Clara, California, or a capacitively coupled plasma (CCP) chemical etch process with ion bombardment using H₂/Ar gas performed in a process chamber, such as one available from Applied Materials of Santa Clara, California.

In block 104 of the method 100, an insulating layer 212 is deposited on the contact surface 208, as shown in FIG. 2B. The insulating layer 212 can be about 1 nm to approximately 10 nm in thickness and include one of the elements within the lanthanide series of chemical elements, as discussed above. Examples of other materials are shown in Tables 1 and 2, shown below.

TABLE 1

| | | | | | Oxide | “M” or |
|---|---|---|---|---|---|---|
| | Work | Formation Energy (eV/atom) | | | Band Gap | “I” in |
| Element | Function | Oxides | Silicides | Nitrides | (eV) | MIS |
| Er | | −4.1 | −0.8 | −2.0 | 5 | I |
| Hf | | −4.0 | −0.8 | −1.9 | 6 | I |
| Y | | −4.0 | −0.9 | −1.9 | 5.5 | I |
| Sc | | −4.0 | −0.8 | −2.1 | 6.3 | I |
| La | | −4.0 | −0.8 | −1.5 | 6 | I |
| Zr | | −3.8 | −0.9 | −1.9 | 5.8 | I |
| Ti | | −3.6 | −0.8 | −1.9 | 0 to ~4-5 | I |
| Al | | −3.4 | 0.3 | −1.6 | 8.8 | I |
| Ta | | −3.4 | −0.6 | −1.4 | 0 to 4.4 | I |
| Si | | −3.3 | NA | −1.3 | 9 | I |
| Eu | 2.5 | −3.1 | −0.6 | −1.0 | 1.5 | M |
| Mg | 3.7 | −3.1 | −0.2 | −0.9 | 7.8 | M |
| V | 4.3 | −2.5 | −0.6 | −1.4 | 0 to ~1 | M |
| Mn | 4.1 | −2.1 | −0.5 | −0.5 | 0 to ~2.5 | M |
| As | 3.8 | −1.6 | −0.1 | 0.3 | Unknown | M |

TABLE 2

| | | | | | | | Oxide | |
|---|---|---|---|---|---|---|---|---|
| | | | Formation Energy - FE (eV/atom) | | | | Band | Melting |
| | Approx. | Resistivity | Ti Inter- | | | | Gap | Point |
| Element | WF (eV) | (10⁻⁸ Ω · m) | metallic | Oxide | Silicides | Nitrides | (eV) | (° C.) |
| Cu | 4.8 | 1.7 | −0.1 | −1.0 | −0.1 | 0.2 | 0 | 1085 |
| Al | 4.16 | 2.7 | −0.4 | −3.4 | 0.3 | −1.6 | >7 | 1225 |
| Zn | 4.27 | 5.9 | −0.2 | −1.8 | 0.5 | 0 | 3.4 | 420 |
| Bi | 4.25 | 129 | −0.2 | −1.7 | 0.5 | 0.5 | 2-4 | 520 |
| In | 4.1 | 8.3 | −0.1 | −2.0 | 0.5 | −0.1 | 2.7-3.7 | 157 |
| As | 3.8 | 30 | −0.9 | −1.6 | −0.1 | 0.3 | 1.3 | 817 |
| Ti | 4.33 | 43 | NA | −3.6 | −0.8 | −1.9 | 0 to 4 | 1668 |
| V | 4.3 | 20 | 0.1 | −2.5 | −0.6 | −1.4 | 0 to 1 | 3470 |
| Mn | 4.1 | 160 | −0.3 | −2.1 | −0.5 | −0.5 | 0 to 2.5 | 2225 |

In block 106 of the method 100, a conductive layer 214 is deposited on the insulating layer 212, as shown in FIG. 2C. The deposition processes may be performed by an ALD, PVD or CVD process, and the deposition of the conductive layer 214 may be from approximately 5 nm to approximately 10 nm in thickness. As discussed above, in some embodiments, the deposition process includes depositing a metal from a metal precursor on the surface of the insulating layer 212. In the deposition process, the metal material forms a less stable oxide than the material used to form the insulating layer 212. In one example, yttrium oxide (Y₂O₃), which has an oxide formation energy of about −4.0, is used to form the insulating layer 212, and aluminum (AI), which has an oxide formation energy of about −3.4, is used to form the conductive layer 214.

In some embodiments, the insulating layer 212 deposited during block 104 is formed of a stoichiometric oxide material, and the stoichiometric oxide material becomes a non-stoichiometric material after the conductive layer 214 is deposited on the insulating layer 212.

### Alternate Contact Structure and Processing Method

FIG. 3 is a method 300 of reducing interface resistance of an Epi surface on a substrate in accordance with some embodiments. FIGS. 4A and 4B are referenced during the discussion of the method 300 for illustrative purposes. As shown in FIG. 4A, an MIS contact structure 400 includes an epitaxially grown source/drain (S/D) layer 402 (e.g., SiP or SiGe) of approximately 30 nm to approximately 40 nm in thickness, a silicon cap layer 404 of approximately 1 nm to approximately 10 nm in thickness, and Epi contact structures 406.

In block 302 of the method 300, a surface 408 of the Epi contact structure 406 (referred to simply as “contact surface”) is pre-cleaned to remove any contamination and/or oxides formed on the contact surface 408. In one example, the pre-clean process may include etching the surfaces of the dielectric and contact surface by a plasma assisted etch process using H₂/Ar gas performed in a process chamber, such as one available from Applied Materials of Santa Clara, California, or a capacitively coupled plasma (CCP) chemical etch process with ion bombardment using H₂/Ar gas performed in a process chamber, such as one available from Applied Materials of Santa Clara, California.

In block 304 of the method 300, a non-stoichiometric layer 412 is deposited on the contact surface 208, as shown in FIG. 4B. The non-stoichiometric layer 412 can be about 1 nm to approximately 10 nm in thickness and comprise one or more metal containing oxides that is stoichiometrically deficient in the amount of oxygen or nitrogen, as discussed above. The non-stoichiometric material formed within the non-stoichiometric layer 412 will have an oxide or nitride deficiency such that the layer has a desired conductivity, and it is formed with a material that has a desired work-function.

### Hardware Configuration Examples

The methods described herein may be performed in individual process in chambers that may be provided in a standalone configuration or as part of a cluster tool, for example, an integrated tool 1000 (i.e., cluster tool) described below with respect to FIG. 5. The advantage of using an integrated tool 1000 is that there is no vacuum break and, therefore, no requirement to degas and, in some cases, pre-clean a substrate before treatment. In some embodiments, the present methods discussed above may advantageously be performed in an integrated tool such that there are limited or no vacuum breaks between processes, reducing vacuum breaks may limit or prevent contamination of the substrate as well as increase the throughput of the processes. The integrated tool 1000 includes a processing platform 1001 that is vacuum-tight, a factory interface 1004, and a system controller 1002. The processing platform 1001 comprises multiple process chambers, such as 1014A, 1014B, 1014C, 1014D, 1014E, and 1014F operatively coupled to a vacuum substrate transfer chamber (transfer chambers 1003A, 1003B). The factory interface 1004 is operatively coupled to the transfer chamber 1003A by one or more load lock chambers (two load lock chambers, such as 1006A and 1006B shown in FIG. 5).

In some embodiments, the factory interface 1004 comprises at least one docking station 1007, at least one factory interface robot 1038 to facilitate the transfer of the semiconductor substrates. The docking station 1007 is configured to accept one or more front opening unified pod (FOUP). Four FOUPS, such as 1005A, 1005B, 1005C, and 1005D are shown in the embodiment of FIG. 5. The factory interface robot 1038 is configured to transfer the substrates from the factory interface 1004 to the processing platform 1001 through the load lock chambers, such as 1006A and 1006B. Each of the load lock chambers 1006A and 1006B have a first port coupled to the factory interface 1004 and a second port coupled to the transfer chamber 1003A. The load lock chamber 1006A and 1006B are coupled to a pressure control system (not shown) which pumps down and vents the load lock chambers 1006A and 1006B to facilitate passing the substrates between the vacuum environment of the transfer chamber 1003A and the substantially ambient (e.g., atmospheric) environment of the factory interface 1004. The transfer chambers 1003A, 1003B have vacuum robots 1042A, 1042B disposed in the respective transfer chambers 1003A, 1003B. The vacuum robot 1042A is capable of transferring substrates 1021 between the load lock chamber 1006A, 1006B, the process chambers 1014A and 1014F and a cool-down station 1040 or a pre-clean station 1042. The vacuum robot 1042B is capable of transferring substrates 1021 between the cool-down station 1040 or pre-clean station 1042 and the process chambers 1014B, 1014C, 1014D, and 1014E.

In some embodiments, the process chambers 1014A, 1014B, 1014C, 1014D, 1014E, and 1014F are coupled to the transfer chambers 1003A, 1003B. The process chambers 1014A, 1014B, 1014C, 1014D, 1014E, and 1014F comprise at least an atomic layer deposition (ALD) process chamber, a chemical vapor deposition (CVD) process chamber, an ion implantation chamber, and a physical vapor deposition (PVD) process chamber. Additional chambers may also be provided such as annealing chambers, additional CVD chambers, additional ALD chambers, additional PVD chambers, or the like. ALD, CVD, ion implantation, and PVD chambers may include any chambers suitable to perform all or portions of the methods described herein, as discussed above. In some embodiments, one or more optional service chambers (shown as 1016A and 1016B) may be coupled to the transfer chamber 1003A. The service chambers 1016A and 1016B may be configured to perform other substrate processes, such as degassing, orientation, substrate metrology, cool down and the like.

The system controller 1002 controls the operation of the integrated tool 1000 using a direct control of the process chambers 1014A, 1014B, 1014C, 1014D, 1014E, and 1014F or alternatively, by controlling the computers (or controllers) associated with the process chambers 1014A, 1014B, 1014C, 1014D, 1014E, and 1014F and the integrated tool 1000. In operation, the system controller 1002 enables data collection and feedback from the respective chambers and systems to optimize performance of the integrated tool 1000. The system controller 1002 generally includes a Central Processing Unit (CPU) 1030, a memory 1034, and a support circuit 1032. The CPU 1030 may be any form of a general-purpose computer processor that can be used in an industrial setting. The support circuit 1032 is conventionally coupled to the CPU 1030 and may comprise a cache, clock circuits, input/output subsystems, power supplies, and the like. Software routines, such as the methods as described above may be stored in the memory 1034 and, when executed by the CPU 1030, transform the CPU 1030 into a specific purpose computer (system controller 1002). The software routines may also be stored and/or executed by a second controller (not shown) that is located remotely from the integrated tool 1000.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of forming an electrical contact, comprising:
depositing an insulating layer that comprises a first material on a contact surface, wherein the first material has a first formation energy; and
depositing a conductive layer that comprises a second material over a surface of the insulating layer, wherein the second material has a second formation energy, and the second formation energy is less than the first formation energy.

2. The method of claim 1, wherein the first material comprises yttrium oxide, and the second material comprises aluminum.

3. The method of claim 1, wherein the first material is deposited using atomic layer deposition.

4. The method of claim 1, wherein the first material comprises at least one of HfO₂, ZrO₂, La₂O₃, Y₂O₃, Ta₂O₅, SiO₂, Eu₂O₃, SC₂O₃, and Gd₂O₃, and the second material comprises a metal selected from a group of Eu, Mg, V, Mn, Al, Bi, Zn, In, W, and As.

5. The method of claim 1, wherein the as deposited insulating layer comprises a stoichiometric oxide material, and the stoichiometric oxide material becomes a non-stoichiometric material after the second material of the conductive layer is deposited on the insulating layer.

6. The method of claim 1, wherein the contact surface comprises silicon (Si).

7. The method of claim 1, wherein neither the first material nor the second material comprises titanium (Ti).

8. A method of forming an electrical contact, comprising:
depositing a non-stoichiometric layer that comprises a first material on a contact surface, wherein the contact surface comprises silicon (Si), and the first material comprises oxygen and the first material is non-stoichiometrically deficient in oxygen.

9. The method of claim 8, wherein the first material comprises yttrium oxide.

10. The method of claim 8, wherein the first material comprises an element selected from the lanthanide series.

11. The method of claim 8, wherein the first material comprises an element selected from a group of Hf, La, Y, Ta, Si, Eu, Sc, Gd, Eu, Mg, V, Mn, Al, Bi, Zn, In, and As.

12. The method of claim 8, wherein the formation energy of the first material to form a metal oxide is greater than the formation energy of a silicon oxide.

13. The method of claim 8, wherein the first material does not comprise titanium (Ti).

14. A semiconductor structure, comprising:
an insulating layer that comprises a first material on a contact surface, wherein the first material has a first formation energy; and
a conductive layer that comprises a second material over a surface of the insulating layer, wherein the second material has a second formation energy, and the second formation energy is less than the first formation energy.

15. The semiconductor structure of claim 14, wherein the first material comprises yttrium oxide, and the second material comprises aluminum.

16. The semiconductor structure of claim 14, wherein:
the first material comprises the first material comprises at least one of HfO₂, ZrO₂, La₂O₃, Y₂O₃, Ta₂O₅, SiO₂, Eu₂O₃, SC₂O₃, and Gd₂O₃.

17. The semiconductor structure of claim 16, wherein:
the second material comprises a metal selected from a group of Eu, Mg, V, Mn, Al, Bi, Zn, In, W, and As.

18. The semiconductor structure of claim 15, wherein the contact surface comprises silicon (Si).

19. The semiconductor structure of claim 15, wherein neither the first material nor the second material comprises titanium (Ti).

20. The semiconductor structure of claim 15, wherein the first material comprises oxygen and the first material is non-stoichiometrically deficient in oxygen.
